(19) United States
(12) Patent Application Publication
(10) Pub. No.: US 2025/0067896 A1
(43) Pub. Date: Feb. 27, 2025

(54) TRANSMISSION DEVICE AND METHOD FOR MULTI-FREQUENCY EQUAL-AMPLITUDE NON-HARMONIC ELECTRICAL PROSPECTING SIGNAL

(71) Applicant: HUNAN UNIVERSITY OF SCIENCE AND TECHNOLOGY, Xiangtan (CN)

(72) Inventors: Guohong FU, Xiangtan (CN); Lijuan YANG, Xiangtan (CN); Shijie WANG, Xiangtan (CN); Hui CHENG, Xiangtan (CN); Songyuan FU, Xiangtan (CN); Tianchun YANG, Xiangtan (CN)

(21) Appl. No.: 18/945,450

(22) Filed: Nov. 12, 2024

(30) Foreign Application Priority Data
Dec. 8, 2023 (CN) 202311675702.5

(51) Int. Cl. G01V 3/12; H03F 3/24; H03F 3/45; H04B 1/04

(52) U.S. Cl. CPC G01V 3/12; H03F 3/245; H03F 3/45475; H04B 1/0475; H04B 2001/0408

(57) ABSTRACT

A transmission device for multi-frequency equal-amplitude non-harmonic electrical prospecting signal includes a single-chip microcontroller, a field programmable gate array (FPGA), a digital to analog conversion (DAC) module, an isolation amplifier circuit, a differential amplifier module, a digital power amplifier circuit, and a sensor module connected successively. A plurality of output ends of the digital power amplifier circuit is in cascade connection with a grounding electrode A and a grounding electrode B to form a loop with ground. An input end of the sensor module is connected with the digital power amplifier circuit. An output end of the sensor module is connected with the single-chip microcontroller.

### CROSS-REFERENCE TO RELATED APPLICATIONS

This application claims the benefit of priority from Chinese Patent Application No. 202311675702.5, filed on Dec. 8, 2023. The content of the aforementioned application, including any intervening amendments thereto, is incorporated herein by reference in its entirety.

### TECHNICAL FIELD

This application relates to electrical prospecting, and more particularly to a transmission device and method for multi-frequency equal-amplitude non-harmonic electrical prospecting signal.

### BACKGROUND

Frequency domain induced polarization method is classified according to the measurement principle, including the frequency variation method, odd harmonic method, dual-frequency induced polarization method and pseudo-random electric method. Commonly used electrical prospecting signal includes variable frequency signal, dual-frequency rectangular wave signal and pseudo-random combined rectangular wave signal. The frequency variation method transmits and receives a rectangular wave signal of a single frequency each time, and performs measurement by successively changing frequencies of transmitting signal and receiving signal. Rectangular wave signal transmitted by the odd harmonic method is a rectangular wave formed by superposition of fundamental wave and a series of odd harmonics, which can receive observation results of the fundamental wave and multiple harmonics and realize simultaneous measurement of the multi-frequency signals. However, through analyzing the spectrum diagram of the rectangular wave, it can be found that an amplitude of each harmonic of the rectangular wave decreases with the increase of the number of times. Therefore, the odd harmonic method actually measures the fundamental wave, triple-frequency harmonic and quintuple-frequency harmonic which is the harmonic less than thirteen times, so as to ensure signal-to-noise ratios of observation signals. The pseudo-random signal scheme is to encode aⁿ sequence of pseudo-random multi-frequency signals, and feed n different frequencies into the ground at the same time, which can extract responses of n frequencies at one time. The dual-frequency signal can be regarded as a specific case of the pseudo-random signal. It can be found from the spectrum diagram that there is a small difference in amplitude heights of two main frequencies of the dual-frequency signal, and amplitudes of received dual-frequency signal are not equal because the fundamental wave with higher frequency rectangular wave includes a certain high-order harmonic component of the lower frequency rectangular wave.

Since the application of frequency domain induced polarization method, the electromagnetically induced coupling effect is one of the main factors affecting the frequency domain induced polarization prospecting. It is found that electromagnetic coupling interference occurs at the moment when the electrical prospecting signal is switched on or switched off. Induction coupling waveform in the time domain waveform shows a very high peak formed by transition edge of waveform, which is mainly caused by high-order harmonic components in the electrical prospecting signal. However, the current electrical prospecting transmitter and the current electromagnetic prospecting transmitter generally adopt driving signals to control the switch-on and switch-off way of the bridge inverter switch, and the external direct current power supplies of the transmitters is are inverted to required rectangular wave current output. Specifically, the current electrical prospecting transmitter and the current electromagnetic prospecting transmitter can only transmit the transition rectangular wave signal, which has rich harmonic components. Such harmonic components eventually become the interference source of the receiving end, and form electromagnetic coupling peaks and harmonic pollution at the receiving end, affecting the quality of observation data and observation accuracy. In addition, when the rectangular wave current is used for ground power supply, although the power conversion efficiency of output stage inverter of the transmitter is relatively high, only the fundamental wave component of the rectangular wave is often used when receiving signals, and the actual utilization rate of the output energy of the transmitter is not very high.

In the electrical prospecting and the electromagnetic prospecting, dual-frequency equal-amplitude signal and multi-frequency equal-amplitude signal with high-voltage and harmonic-free are recognized as ideal controlled source signals in this field.

### SUMMARY

In order to solve the above problems, this application provides a transmission device and method for multi-frequency equal-amplitude non-harmonic electrical prospecting signal.

Technical solutions of this application are as follows.

A transmission device for multi-frequency equal-amplitude non-harmonic electrical prospecting signal is provided, comprising:
a single-chip microcontroller;
a field programmable gate array (FPGA);
a digital to analog conversion (DAC) module;
an isolation amplifier circuit;
a differential amplifier module;
a digital power amplifier circuit; and
a sensor module;
wherein the single-chip microcontroller is connected with an input end of the FPGA; an output end of the FPGA is connected with an input end of the DAC module; an output end of the DAC module is connected with a plurality of input ends of the isolation amplifier circuit; individual output end of the isolation amplifier circuit is connected with individual input end of the differential amplifier module; individual output end of the differential amplifier module is connected with individual input end of the digital power amplifier circuit; a plurality of output ends of the digital power amplifier circuit is in cascade connection with a grounding electrode A and a grounding electrode B to form a loop with ground; an input end of the sensor module is connected with the digital power amplifier circuit; and an output end of the sensor module is connected with the single-chip microcontroller; and the FPGA is configured to output a sine wave signal combined by multiple frequencies in the form of digital signal; the DAC module is configured to convert the digital signal to an analog signal and calculate to obtain a signal source; the signal source is isolated and amplified through the isolation amplifier circuit; the differential amplifier module is configured to adjust a voltage range of the signal source, so that an output voltage range at preceding stage fully matches an input voltage range at following stage; the signal source is subjected to power amplification through a digital power amplifier circuit, and then outputs a controlled source electrical prospecting signal to the ground through the grounding electrode A and the grounding electrode B in the way of single channel, multi-channel output end in parallel, or multi-channel output end in cascade connection.

In an embodiment, the transmission device further comprises a liquid crystal display module, a secure digital (SD) card memory module, an audible and visual alarm module, and a global positioning system (GPS) synchronization module; wherein the liquid crystal display module, the SD card memory module, the audible and visual alarm module and the GPS synchronization module are connected with the single-chip microcontroller.

In an embodiment, the transmission device further comprises a protection module, an independent power supply, and a normally open relay; wherein the protection module is configured for protection of overvoltage, overcurrent and overheating; each independent power supply is connected with individual normally open relay; each normally open relay has two groups of normally open contact configured to control switch-on and switch-off in each independent power supply, respectively; each normally open relay is connected with individual digital power amplifier circuit to supply power to the digital power amplifier circuit; an input end of the protection module is connected with the single-chip microcontroller, and an output end of the protection module is connected with the normally open relay.

In an embodiment, when the transmission device outputs in cascade connection of four channel output ends, an output voltage is 400 peak-to-peak voltage (Vpp), and an output current is above 1.5 A.

In an embodiment, when the transmission device outputs in parallel connection of four channel output ends, the output voltage is 100 Vpp, and the output current is above 6 A.

In an embodiment, the sensor module comprises a voltage transformer ZMPT101B, a current sensor ACS712ELCTPR and a temperature sensor DS18B20.

In an embodiment, the transmission device further comprises a keyboard module; wherein the keyboard module is connected with the single-chip microcontroller and the FPGA.

In an embodiment, the single-chip microcontroller adopts an STM32F103ZET6 chip; the FPGA adopts an EP4CE10E22C8N chip; the DAC module adopts a main chip of AD9767ASTZ; a main chip of the isolation amplifier circuit is ISO124U; and a model of the digital power amplifier circuit is TDA8920CTH.

The transmission device above can also be applied to transmit electromagnetic prospecting signal, and can generate a non-harmonic controlled source signal with high voltage single frequency, or dual-frequency equal-amplitude or multi-frequency equal-amplitude in electrical prospecting and electromagnetic prospecting.

This application also provides a transmission method for multi-frequency equal-amplitude non-harmonic electrical prospecting signal, comprising:
(1) initializing the FPGA, and resetting a system clock signal;
(2) defining a digital to analog (DA) data output clock and a port type of an output channel configured for data output from the FPGA to the DAC module;
(3) defining a frequency control word and a phase control word;
(4) defining an accumulator register, a phase register, a read-only memory (ROM);
(5) instantiating a lookup table, and storing a data containing signal waveform information into the ROM for subsequent invocation;
(6) generating a phase accumulator; accumulating a phase every other clock cycle; and changing, through a button, a value of the frequency control word to control a frequency of a generated signal;
(7) generating a lookup table address; invoking the ROM and changing a value of the phase control word through the button to control an initial phase of the generated signal;
(8) waiting for a direct digital synthesis (DDS) command; if a conditional statement is judged to be true, outputting a digital signal; if the conditional statement is judged to be false, maintaining a waiting state; and
(9) waiting for a digital to analog (DA) clock signal; when a first rising edge of the DA clock signal occurs, collecting the digital signal output in step (8); completing data collection, and converting the digital signal into the analog signal; when a falling edge of the DA clock signal occurs, outputting the analog signal, and completing generation of a sine signal with single frequency or dual-frequency equal-amplitude or multi-frequency equal-amplitude; and if the DA clock signal is not received, the digital signal cannot be collected, and maintaining the waiting state.

This application has the following beneficial effects.
(1) The transmission device of this application can output High voltage sine waves or combined sine wave signals which have high accuracy and relatively high power. Typical examples are frequency conversion sine wave, dual-frequency combined sine wave and multi-frequency combined sine wave signal, such as quintuple-frequency combined sine wave signal.
(2) The electrical prospecting signal or electromagnetic prospecting signal output by the transmission device of this application are significantly different from signals generated by a full bridge inverter transmitter, which only have the main frequency without harmonic components, and can effectively suppress the electromagnetic coupling interference.
(3) Each main frequency of the electrical prospecting signal or electromagnetic prospecting signal output by the transmission device of this application has equal amplitude and uniform energy distribution in spectrogram. The electrical prospecting signal or electromagnetic prospecting signal output by the transmission device of this application can obtain enough response without increasing the current, which improves the signal-to-noise ratios of the received signal of prospecting work and improves the quality of data acquisition.
(4) The dual-frequency non-harmonic electrical prospecting signal, or the multi-frequency non-harmonic electrical prospecting signal, or the low and medium frequency non-harmonic electromagnetic prospecting signal output by the transmission device of this application has equal main frequencies, which can eliminate normalization calibration of the receiver, simplify the circuit design of the receiver, and is convenient for construction.
(5) The electrical prospecting signal output by the transmission device is simultaneously subjected to analog differential amplification and digital power amplification, which can flexibly adjust the output voltage range. In addition, the transmission device is light and easy to carry, which is suitable for prospecting occasions with complex terrain.

### BRIEF DESCRIPTION OF THE DRAWINGS

FIG. 1 is a block diagram of an overall structure of a transmission device for multi-frequency equal-amplitude non-harmonic electrical prospecting signal according to an embodiment of the present disclosure.

FIG. 2 shows a principle diagram of a single channel signal output circuit according to an embodiment of the present disclosure.

FIG. 3 shows a principle diagram of an isolation amplifier circuit according to an embodiment of the present disclosure.

FIG. 4 shows a principle diagram of a digital power amplifier circuit according to an embodiment of the present disclosure.

FIG. 5 is a flow chart of a transmission method for multi-frequency equal-amplitude non-harmonic electrical prospecting signal according to an embodiment of the present disclosure.

FIG. 6(a) shows a diagram of a single-frequency rectangular wave according to an embodiment of the present disclosure.

FIG. 6(b) shows a spectrogram diagram of the single-frequency rectangular wave of FIG. 6(a).

FIG. 6(c) shows a diagram of a single-frequency sine signal according to an embodiment of the present disclosure.

FIG. 6(d) shows a spectrogram diagram of the single-frequency sine signal of FIG. 6(c).

FIG. 7(a) shows a diagram of a dual-frequency rectangular wave according to an embodiment of the present disclosure.

FIG. 7(b) shows a spectrogram diagram of the dual-frequency rectangular wave of FIG. 7(a).

FIG. 7(c) shows a diagram of a dual-frequency sine signal according to an embodiment of the present disclosure.

FIG. 7(d) shows a spectrogram diagram of the dual-frequency sine signal of FIG. 7(c).

FIG. 8(a) shows a diagram of a traditional quintuple-frequency rectangular wave.

FIG. 8(b) shows a spectrogram diagram of the traditional quintuple-frequency rectangular wave of FIG. 8(a).

FIG. 8(c) shows a diagram of a quintuple-frequency sine signal wave according to an embodiment of the present disclosure.

FIG. 8(d) shows a spectrogram diagram of the quintuple-frequency sine signal wave of FIG. 8(c).

### DETAILED DESCRIPTION OF EMBODIMENTS

The present disclosure will be further described with reference to the accompanying drawings and embodiments.

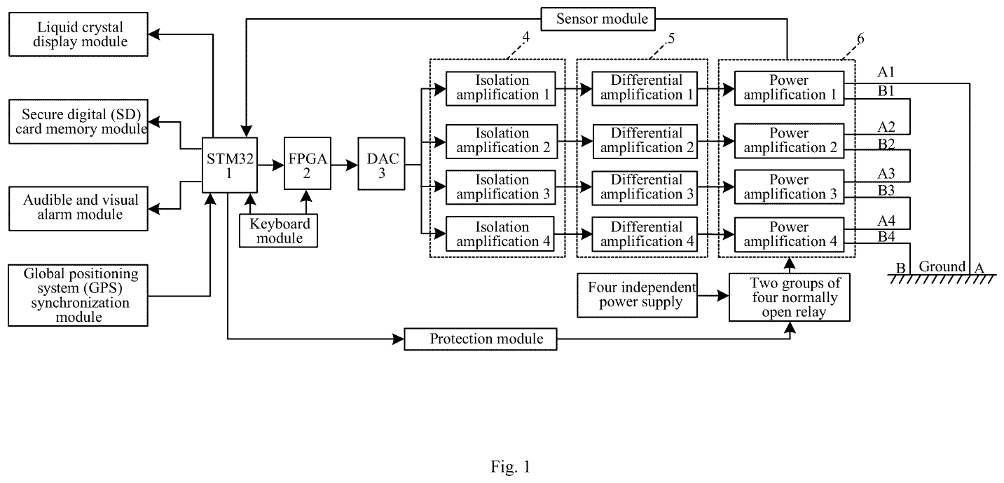

Referring to FIG. 1, a transmission device for multi-frequency equal-amplitude non-harmonic electrical prospecting signal is provided includes a single-chip microcontroller 1, a field programmable gate array (FPGA) 2, a digital to analog conversion (DAC) module 3, an isolation amplifier circuit 4, a differential amplifier module 5, a digital power amplifier circuit 6, a sensor module, a liquid crystal display module, a secure digital (SD) card memory module, an audible and visual alarm module, a global positioning system (GPS) synchronization module, a protection module configured for protection of overvoltage, overcurrent and overheating, an independent power supply, a normally open relay and a keyboard module. The single-chip microcontroller 1 is connected with an input end of the FPGA 2. The keyboard module is connected with the single-chip microcontroller 1 and the FPGA 2 to complete generation of a signal source. An output end of the FPGA 2 is connected with an input end of the DAC module 3. An output end of the DAC module 3 is connected with four input ends of the isolation amplifier circuits 4 to prevent an interference between a preceding stage and a following stage. Individual output end of the isolation amplifier circuits 4 is connected with individual input end of the differential amplifier module 5. Individual output end of the differential amplifier module 5 is connected with individual input end of the digital power amplifier circuit 6. Four output ends of the digital power amplifier circuit 6 are in cascade connection with a grounding electrode A and a grounding electrode B to form a loop with ground. An input end of the sensor module is connected with the digital power amplifier circuit 6. An output end of the sensor module is connected with the single-chip microcontroller 1.

The transmission device of the present disclosure adopts a direct digital synthesis (DDS) technology to generate a required waveform by a mode of FPGA and DAC. The FPGA 2 is configured to output a sine wave signal combined by multiple frequencies in the form of digital signal. A 14-bit binary digital input end (14 wires) of each channel of the DAC module 3 in dual-channel mode is connected with the FPGA 2 to receive the digital signal, and is configured to convert the digital signal into an analog signal and output a smooth and clean sine wave. The DAC module 3 includes a current-voltage conversion circuit and a voltage amplifier circuit, which are configured to convert a differential current signal output by a main chip of the DAC module 3 into a voltage signal and adjust an output range of the voltage signal. The DAC module 3 of the present disclosure are configured to simultaneously output two signals, and the two signals are subjected to signal processing to obtain a required signal source. In order to meet the requirements of output with high voltage and relatively large current of electrical prospecting, a multi-stage digital power amplifier cascade connection is adopted to externally output. The isolation amplifier circuits 4 is designed to realize electrical isolation between the signal source and a following circuit. The signal source is isolated and amplified, and then is differentially amplified according to a digital power amplifier device. A voltage range of the signal source is adjusted, so that a preceding voltage output range fully matches a following voltage output range. The signal source is subjected to power amplification through a digital power amplifier circuit, and is directly connected to the grounding electrode A and the grounding electrode B to form the loop with the ground, or outputs after cascade connection of output ends of multi digital power amplifiers, so as to supply power to the ground to realize transmitting and output of a whole multi-frequency equal-amplitude non-harmonic electrical (electromagnetic) prospecting signal. In addition, the transmission device has functions of real-time monitoring of voltage, current and temperature, audible and visual alarm, and protection of overvoltage, overcurrent, overheating and so on.

The liquid crystal display module, the SD card memory module, the audible and visual alarm module and the GPS synchronization module are connected with the single-chip microcontroller 1. The liquid crystal display module is configured to display a current temperature, time, output voltage, current value and remaining storage capacity of a secure digital (SD) card. The SD card memory module is configured to save an information, such as voltage, current and temperature, of each signal output of the transmission device in file form. The GPS synchronization module is configured to ensure a frequency accuracy of signal output, and maintain precise synchronization with a receiver with a GPS module. Each independent power supply is connected with individual normally open relay. Each normally open relay has two groups of normally open contact configured to control switch-on and switch-off in each independent power supply, respectively. Each normally open relay is connected with individual digital power amplifier circuit to supply power to the digital power amplifier circuit 6. An input end of the protection module is connected with the single-chip microcontroller 1, and an output end of the protection module is connected with the normally open relay.

When the transmission device outputs in cascade connection of four channel output end, an output voltage is 400 peak-to-peak voltage (Vpp), and an output current is above 1.5 A. When the transmission device outputs in parallel connection of four channel output ends, the output voltage is 100 Vpp, and the output current is above 6 A.

The sensor module adopts a voltage transformer ZMPT101B, a current sensor ACS712ELCTPR and a temperature sensor DS18B20; where the voltage transformer and an input end of the current sensor are connected with the digital power amplifier circuit; the temperature sensor is close to the digital power amplifier circuit; and the temperature sensor DS18B20 can be regarded as a plastic capsulation and is configured to sense a heat source temperature.

The single-chip microcontroller 1 adopts an STM32F103ZET6 chip. The FPGA adopts an EP4CE10E22C8N chip. The DAC module adopts a main chip of AD9767ASTZ. A main chip of the isolation amplifier circuit is ISO124U. A model of the digital power amplifier circuit is TDA8920CTH.

Under the premise of GPS synchronization or wired synchronization, the transmission device can output a combined sine current with 400 Vpp and 1.5 A, and two transmission devices can output a current with 800 Vpp and 1.5 A. The present disclosure has potentials to further improve the output voltage and the output current. A transmitted controlled source electrical (electromagnetic) prospecting signal does not contain harmonic components, which effectively suppresses electromagnetic coupling peaks and harmonic interferences of rectangular wave outputs by traditional frequency domain electrical and electromagnetic prospecting, and effectively suppresses peak voltages and harmonic pollutions when the receiver receives the signal.

Referring to FIG. 1, the transmission device of the present disclosure adopts an advanced reduced instruction set computer (RISC) machine (ARM) 32-bit single-chip microcontroller (STM32) as a main control chip. The transmission device is started, and the STM32 is started. A system clock, the liquid crystal display module, the SD card memory module, and the GPS synchronization module are initialized, and then the transmission device enters a standby mode. An operation button is pressed, and the transmission device enters an operating mode. The liquid crystal display module displays the following information: signal type selection, transmitting start time, transmitting end time, transmitting voltage, output current, temperature of digital power amplifier, SD card storage state, current time. A users can select a type, a frequency and a phase of the signal transmitted by the FPGA through the button. Then a start button is pressed to transmit the signal, and an end button is pressed after operation completion. The FPGA receives a level signal of the transmitting signal, then the FPGA transmits a specific digital signal according to command requirements, and the specific digital signal is converted into the analog signal by the DAC module. The analog signal is a low voltage signal. The analog signal is isolated and amplified by a linear isolation amplifier circuits 4, and then its voltage range is adjusted by the differential amplifier module to match with an input voltage range of a digital power amplifier circuit. The adjusted signal is input to the digital power amplifier circuit followed by power amplification to obtain an output voltage wave signal transmitted by the transmission device of the present disclosure. An output end of the transmission device is connected with the grounding electrode A and the grounding electrode B to form the loop to supply power to the ground.

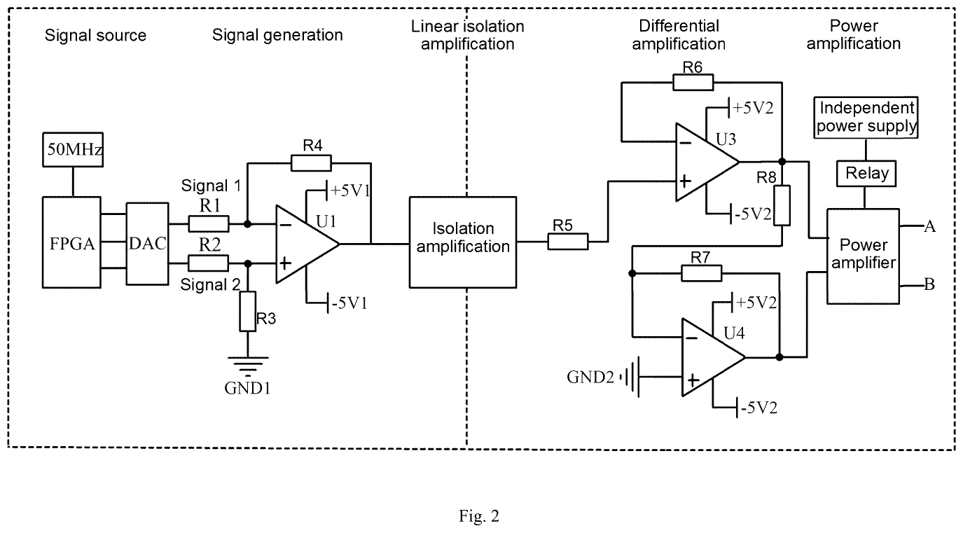

Referring to FIG. 2, which shows a principle diagram of a single channel signal output circuit. The transmission device of the present disclosure can output the multi-frequency equal-amplitude non-harmonic electrical (electromagnetic) prospecting signal in the single channel, or output high voltage controlled source electrical (electromagnetic) prospecting signal in output ends of four isolation amplifier channels in cascade connection. The four isolation amplifier channels and the single channel have the same circuit design. A generation principle of the single-frequency sine signal, a 4 Hz and 4/13 Hz dual-frequency combined sine signal and the quintuple-frequency sine signal are described below with reference to FIG. 2.

A mode of the FPGA+DAC generates different types of sine signal or combined sine wave signal. In the case of the single-frequency sine signal, the FPGA only outputs one digital signal to one digital input channel, and the other digital input channel does not generate the signal. In the case of the dual-frequency signal, the FPGA outputs a 4 Hz signal and a 4/13 Hz signal to two digital input channels of the DAC. In the case of the quintuple-frequency signal, the FPGA outputs a first combined digital signal of two frequencies to one digital input channel, and outputs a second combined digital signal of three frequencies to the other digital input channel. The DAC converts the digital signal to the analog signal. The analog signal is output through two output ends of the two digital input channels. One of the two output ends of the two digital input channels is connected with a left end of a resistance R1, and the other of the two output ends of the two digital input channels is connected with a left end of a resistance R2. The two signals are transmitted to an inverting proportional amplifier circuit combined by the resistance R1, the resistance R2, a resistance R3, a resistance R4 and an operational amplifier U1. A right end of the resistance R1 is connected with an inverting input end of the operational amplifier U1. A right end of the resistance R2 is connected with a non-inverting input end of the operational amplifier U1. An upper end of the resistance R3 is connected with the non-inverting input end of the operational amplifier U1, and a lower end of the resistance R3 is connected with the ground. A left end of the resistance R4 is connected with the inverting input end of the operational amplifier U1, and a right end of the resistance R4 is connected with an output end of the operational amplifier U1. The operational amplifier U1 powered by a dual-power supply of +5V and −5V A signal 1 and a signal 2 pass through an operational circuit and output a 4 Hz and 4/13 Hz combined dual-frequency sine wave signal through the output end of the operational amplifier U1. The signal after isolation and amplification flows through a left end of a resistance R5. The resistance R5, a resistance R6, a resistance R7, a resistance R8, an operational amplifier U3 and an operational amplifier U4 constitute a differential amplifier circuit to complete differential conversion of the signal to obtain a signal consistent with a voltage input range of a power amplifier chip, and the signal is subjected to the digital power amplifier circuit to obtain an output voltage and an output current meet the requirements of electrical prospecting, which are configured to supply power to the ground through the grounding electrode A and the grounding electrode B.

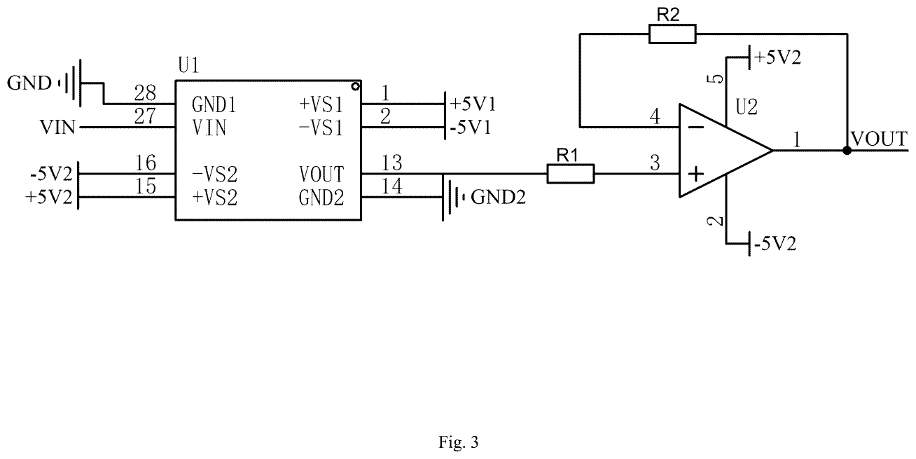

FIG. 3 shows an isolation amplifier circuit of the transmission device of the present disclosure. A high-precision linear isolation amplifier with the main chip of the isolation amplifier circuit of ISO124U can transmit the signal in digital form through a 2 picofarad (pF) differential capacitive isolation layer. A differential current signal is output from a DAC circuit in the main chip of ISO124U, and is converted into the voltage signal through a current-voltage conversion circuit. An input signal of the isolation amplifier circuit is input from a first pin marked with signal input port (VIN) of the main chip of ISO124U, and the input signal of the isolation amplifier circuit is subjected to isolation amplification by the main chip of ISO124U and then flows into a following signal adjusting circuit. The following signal adjusting circuit is a voltage follower combined by the resistance R1, the resistance R2 and an operational amplifier U2. The output signal output from a second pin 13 of the main chip of ISO124U is connected with the left end of the resistance R1, and the right end of the resistance R1 is connected with a non-inverting input end of the operational amplifier U2. The left end of the resistance R2 is connected with an inverting input end of the operational amplifier U2, and the right of the resistance R2 is connected with an output end of the operational amplifier U2. The signal after isolation and amplification is output from a third pin marked with output voltage (VOUT) (that is, the output end of the operational amplifier U2) and then is output to a following circuit (differential amplifier circuit). The ISO124U and the operational amplifier U2 are powered by the dual-power supply of +5V and −5V

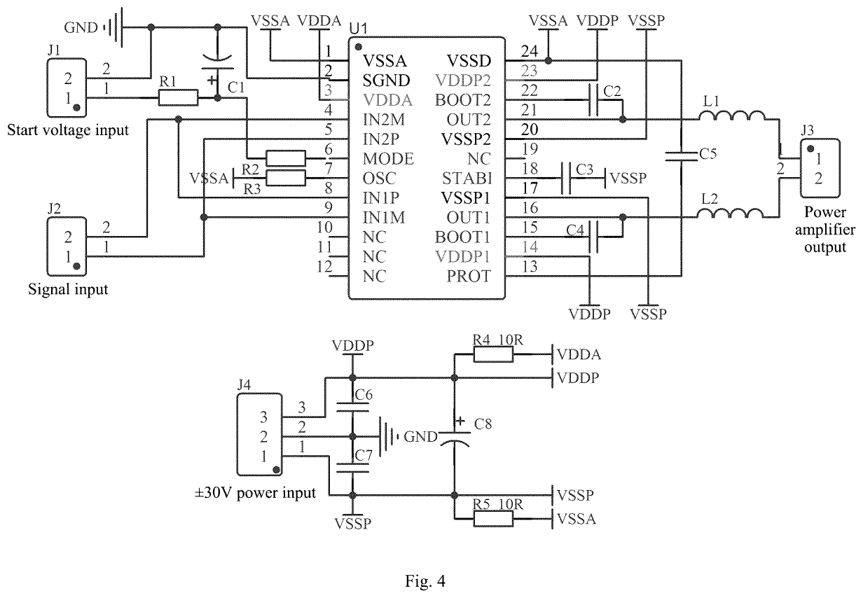

FIG. 4 shows the digital power amplifier circuit of the present disclosure. A digital power amplifier part of the present disclosure is composed of a chip of power amplifier TDA8920CTH and its peripheral circuit. The chip of TDA8920CTH is powered by a power supply of 30V A peripheral supply voltage (VDDP) is connected with the power supply of +30V An analog supply voltage (VDDA) is connected with the VDDP through the resistance R4. A peripheral voltage source negative (VSSP) is connected with the power supply of −30V An analog voltage source negative (VSSA) is connected with the VSSP through the resistance R5. A fourth pin 6 is a mode selection pin of the chip of the digital power amplifier circuit TDA8920CTH. The fourth pin 6, the resistance R1, the resistance R2, a capacitance C1 and a terminal block J1 are configured to make the chip of the digital power amplifier circuit TDA8920CTH in a corresponding operation mode. The terminal block J1 is an input end of a start voltage, and is connected with the power supply of +5V A fifth pin 4 is a negative audio input of a first amplifier 2 in the chip of TDA8920CTH, and a sixth pin 5 is a positive audio input of the first amplifier 2. A seventh pin 9 is a negative audio input of a second amplifier 1 in the chip of TDA8920CTH, and an eighth pin 8 is a positive audio input of the second amplifier 1. In the case of single-channel input of the present disclosure, the positive audio input of the first amplifier 2 is connected with the negative audio input of the second amplifier 1, and is connected with a 1 pin of a signal input end J2. The negative audio input of the first amplifier 2 is connected with the negative audio input of the second amplifier 1, and is connected with a 2 pin of the signal input end J2. A ninth pin 21 and a tenth pin 16 are differential current output ends after the power amplification.

The transmission device of the present disclosure is also applied to transmit electromagnetic prospecting signal, and can generate a non-harmonic controlled source signal with high voltage single frequency, or dual-frequency equal-amplitude or multi-frequency equal-amplitude in electrical prospecting and electromagnetic prospecting.

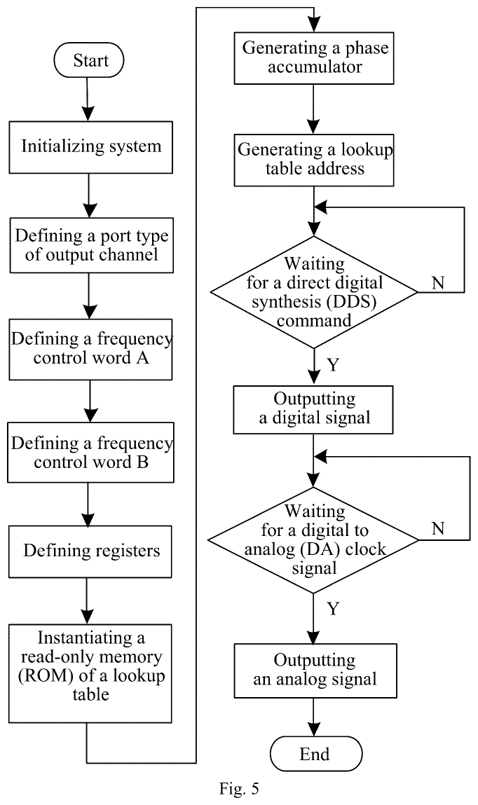

Referring to FIG. 5, the transmission device of the present disclosure adopts a direct digital synthesis (DDS) principle. A flow chart of a software of signal generation by FPGA+DAC is shown in FIG. 5, including the following steps.
(1) The FPGA is initialized, and a system clock signal is reset.
(2) A digital to analog (DA) data output clock and a port type of an output channel configured for data output from the FPGA to the DAC module are defined.
(3) A frequency control word and a phase control word are defined.
(4) An accumulator register, a phase register, and a read-only memory (ROM) are defined.
(5) A lookup table is instantiated, and a data containing signal waveform information is stored into the ROM for subsequent invocation.
(6) A phase accumulator is generated. A phase is accumulated every other clock cycle, and a value of the frequency control word is changed through a button to control a frequency of a generated signal.
(7) A lookup table address is generated. The ROM is invoked. A value of the phase control word is changed through the button to control an initial phase of the generated signal.
(8) A direct digital synthesis (DDS) command is waited for. If a conditional statement is judged to be true, a digital signal is output. If the conditional statement is judged to be false, a waiting state is maintained.
(9) A digital to analog (DA) clock signal is waited for. When a first rising edge of the DA clock signal occurs, the digital signal output in step (8) is collected, and the digital signal is converted into the analog signal after completion of data collection. When a falling edge of the DA clock signal occurs, the analog signal is output, and generation of a sine signal with single frequency or dual-frequency equal-amplitude or multi-frequency equal-amplitude is completed. If the DA clock signal is not received, the digital signal cannot be collected, the waiting state is maintained.

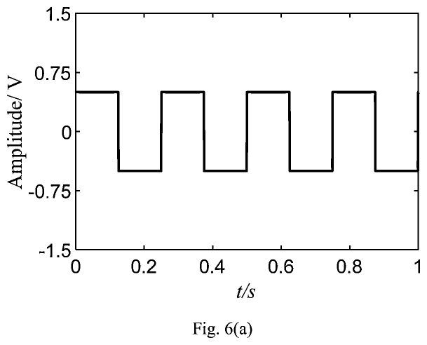

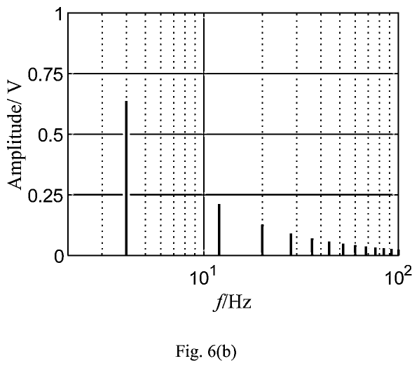

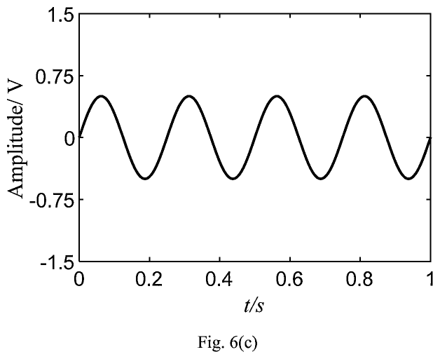

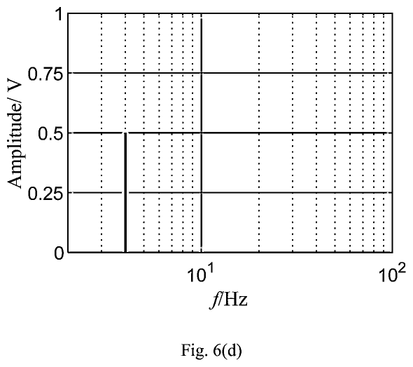

FIGS. 6 (a)-(d) respectively shows a diagram of a single-frequency rectangular wave, a spectrogram diagram of the single-frequency rectangular wave, a diagram of a single-frequency sine signal, and a spectrogram diagram of the single-frequency sine signal. Compared to the spectrogram diagrams, the single-frequency rectangular wave is formed by superposition of a sine wave as a main frequency and other multiple harmonics. The present disclosure directly generates a single-frequency sine current output without harmonic components.

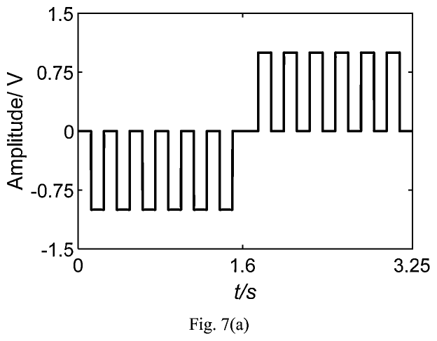

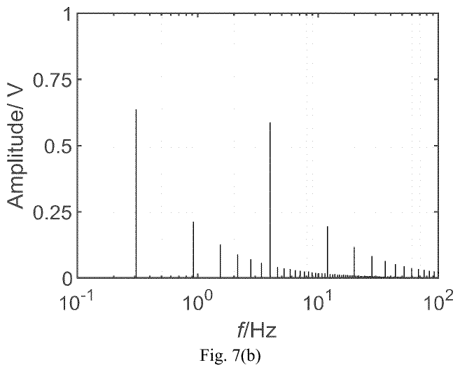

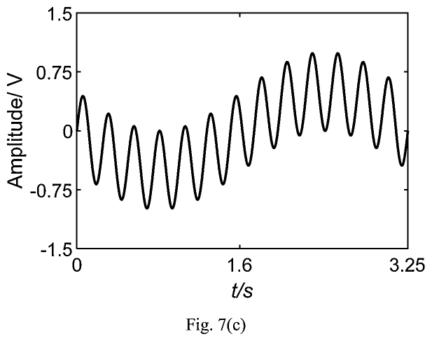

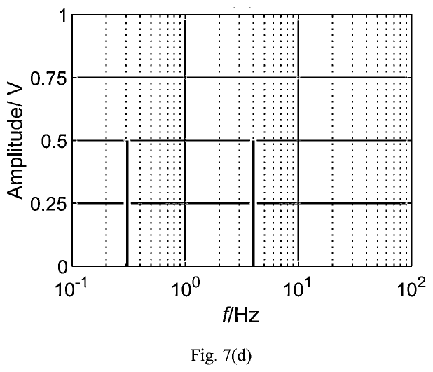

FIGS. 7(a)-(d) respectively shows a diagram of a dual-frequency rectangular wave, a spectrogram diagram of the dual-frequency rectangular wave, a diagram of a dual-frequency sine signal, and a spectrogram diagram of the dual-frequency sine signal. Compared to the spectrogram diagrams, the dual-frequency rectangular wave is formed by superposition of a fundamental wave of rectangular wave with high and low two frequencies and their odd harmonics. The present disclosure directly generates two single-frequency sine current outputs without harmonic components.

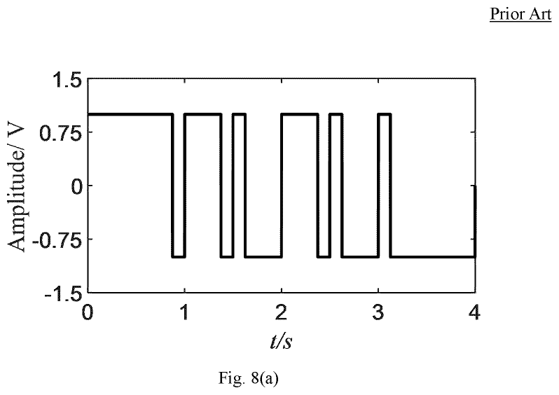

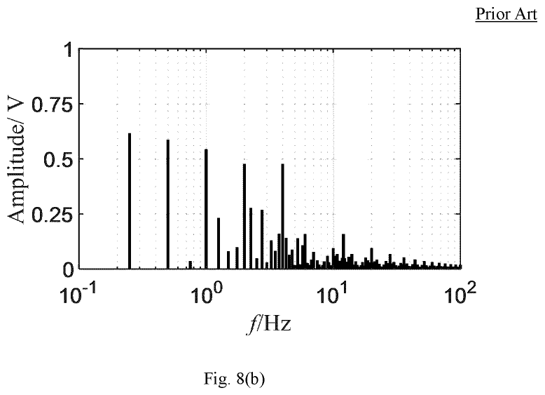

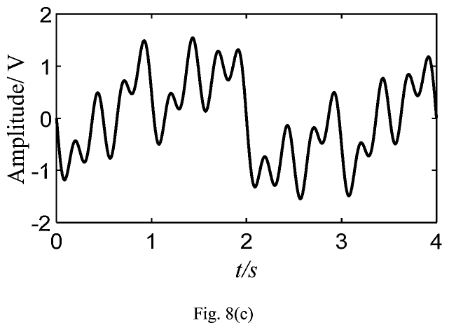

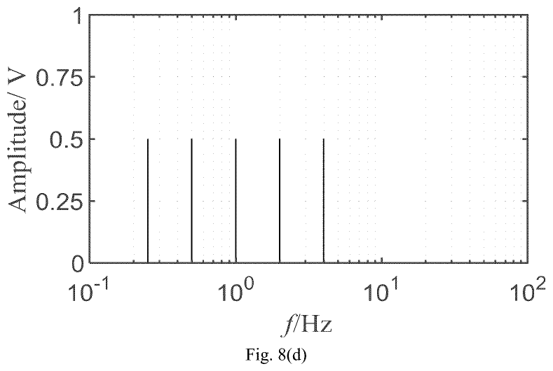

FIGS. 8(a)-(d) respectively shows a diagram of a traditional quintuple-frequency rectangular wave, a spectrogram diagram of the traditional quintuple-frequency rectangular wave, a diagram of a quintuple-frequency sine signal wave, and a spectrogram diagram of the quintuple-frequency sine signal wave. Compared to the spectrogram diagrams, the quintuple-frequency sine signal wave is formed by superposition of a fundamental wave of rectangular wave with five frequencies and their odd harmonics. The present disclosure directly generates five single-frequency sine current outputs without harmonic components, and the five single-frequency have the same amplitude.

What is claimed is:

1. A transmission device for multi-frequency equal-amplitude non-harmonic electrical prospecting signal, comprising:
a single-chip microcontroller;
a field programmable gate array (FPGA);
a digital to analog conversion (DAC) module;
an isolation amplifier circuit;
a differential amplifier module;
a digital power amplifier circuit; and
a sensor module;
wherein the single-chip microcontroller is connected with an input end of the FPGA; an output end of the FPGA is connected with an input end of the DAC module; an output end of the DAC module is connected with a plurality of input ends of the isolation amplifier circuit; individual output end of the isolation amplifier circuit is connected with individual input end of the differential amplifier module; individual output end of the differential amplifier module is connected with individual input end of the digital power amplifier circuit; a plurality of output ends of the digital power amplifier circuit is in cascade connection with a grounding electrode A and a grounding electrode B to form a loop with ground; an input end of the sensor module is connected with the digital power amplifier circuit; and an output end of the sensor module is connected with the single-chip microcontroller; and
the FPGA is configured to output a sine wave signal combined by multiple frequencies in the form of digital signal; the DAC module is configured to convert the digital signal to an analog signal and calculate to obtain a signal source; the signal source is isolated and amplified through the isolation amplifier circuit; the differential amplifier module is configured to adjust a voltage range of the signal source, so that an output voltage range at preceding stage fully matches an input voltage range at following stage; the signal source is subjected to power amplification through a digital power amplifier circuit, and then outputs a controlled source electrical prospecting signal to the ground through the grounding electrode A and the grounding electrode B in the way of single channel, multi-channel output end in parallel, or multi-channel output end in cascade connection.

2. The transmission device of claim 1, further comprising:
a liquid crystal display module;
a secure digital (SD) card memory module;
an audible and visual alarm module; and
a global positioning system (GPS) synchronization module;
wherein the liquid crystal display module, the SD card memory module, the audible and visual alarm module and the GPS synchronization module are connected with the single-chip microcontroller.

3. The transmission device of claim 1, further comprising: a protection module, an independent power supply, a normally open relay; wherein the protection module is configured for protection of overvoltage, overcurrent and overheating; each independent power supply is connected with individual normally open relay; each normally open relay has two groups of normally open contact configured to control switch-on and switch-off in each independent power supply, respectively; each normally open relay is connected with individual digital power amplifier circuit to supply power to the digital power amplifier circuit; an input end of the protection module is connected with the single-chip microcontroller, and an output end of the protection module is connected with the normally open relay.

4. The transmission device of claim 1, wherein in the case that the transmission device outputs in cascade connection of four channel output ends, an output voltage is 400 peak-to-peak voltage (Vpp), and an output current is above 1.5 A.

5. The transmission device of claim 1, wherein in the case that the transmission device outputs in parallel connection of four channel output ends, an output voltage is 100 Vpp, and an output current is above 6 A.

6. The transmission device of claim 1, wherein the sensor module comprises a voltage transformer ZMPT101B, a current sensor ACS712ELCTPR and a temperature sensor DS18B20.

7. The transmission device of claim 1, further comprising a keyboard module; wherein the keyboard module is connected with the single-chip microcontroller and the FPGA.

8. The transmission device of claim 1, wherein the single-chip microcontroller adopts an STM32F103ZET6 chip; the FPGA adopts an EP4CE10E22C8N chip; the DAC module adopts a main chip of AD9767ASTZ; a main chip of the isolation amplifier circuit is ISO124U; and a model of the digital power amplifier circuit is TDA8920CTH.

9. The transmission device of claim 1, wherein the transmission device is also configured to transmit electromagnetic prospecting signal, and generate a non-harmonic controlled source signal with high voltage single frequency, or dual-frequency equal-amplitude or multi-frequency equal-amplitude in electrical prospecting and electromagnetic prospecting.

10. A transmission method for multi-frequency equal-amplitude non-harmonic electrical prospecting signal using the transmission device of claim 1, comprising:
(1) initializing the FPGA, and resetting a system clock signal;
(2) defining a digital to analog (DA) data output clock and a port type of an output channel configured for data output from the FPGA to the DAC module;
(3) defining a frequency control word and a phase control word;
(4) defining an accumulator register, a phase register, a read-only memory (ROM);
(5) instantiating a lookup table, and storing a data containing signal waveform information into the ROM for subsequent invocation;
(6) generating a phase accumulator; accumulating a phase every other clock cycle; and changing, through a button, a value of the frequency control word to control a frequency of a generated signal;
(7) generating a lookup table address; invoking the ROM and changing a value of the phase control word through the button to control an initial phase of the generated signal;
(8) waiting for a direct digital synthesis (DDS) command; if a conditional statement is judged to be true, outputting a digital signal; if the conditional statement is judged to be false, maintaining a waiting state; and
(9) waiting for a digital to analog (DA) clock signal; when a first rising edge of the DA clock signal occurs, collecting the digital signal output in step (8); completing data collection, and converting the digital signal into the analog signal; when a falling edge of the DA clock signal occurs, outputting the analog signal, and completing generation of a sine signal with single frequency or dual-frequency equal-amplitude or multi-frequency equal-amplitude; and if the DA clock signal is not received, the digital signal cannot be collected, and maintaining the waiting state.
